(19) United States
(12) Patent Application Publication
(10) Pub. No.: US 2009/0322917 A1
(43) Pub. Date: Dec. 31, 2009

(54) SOLID-STATE IMAGING DEVICE

(75) Inventors: Masanori Kyogoku, Osaka (JP); Kenichi Shimomura, Hyogo (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/477,453

(22) Filed: Jun. 3, 2009

(30) Foreign Application Priority Data
Jun. 25, 2008 (JP) 2008-165859

(51) Int. Cl. H04N 5/335

(52) U.S. Cl. 348/273; 348/E05.091

(57) ABSTRACT

It is an object of the present invention to provide a solid-state imaging device capable of operating at high-speed, and suppressing the deterioration of image quality caused by coupling. A solid-state imaging device according to the present invention includes: pixels arranged in rows and columns; color filters each of which is arranged on a light incidence plane of a corresponding one of the pixels, each of the color filters being one of at least two colors; and column signal lines provided for each of the columns of the pixels, and each of which transmits the signals from the pixels in a column direction, in which one of the color filters is arranged on one of the pixels connected to the column signal line, and is of a same color as another one of the color filters arranged on another one of the pixels connected to the column signal line.

### BACKGROUND OF THE INVENTION

(1) Field of the Invention

The present invention relates to an amplifying (MOS) solid-state imaging device which amplifies and takes out signal charge generated in a photoelectric conversion unit, and particularly relates to a solid-state imaging device equipped with color filters.

(2) Description of the Related Art

In recent years, CCD and MOS solid-state imaging devices used for video cameras and electronic still cameras have significantly developed to a point where the size of a unit pixel is miniaturized to 2 μm² or less and the number of pixels exceeds 10 million pixels. Furthermore, there is an increasing request for accelerating the read-out time which is a tradeoff with the increase in the number of pixels. Thus, it is necessary to maintain the frame rate despite the increase in the number of pixels. Accordingly, even if the number of pixels increases, it is necessary for the solid-state imaging devices to secure higher image quality and a speed equivalent to or higher than the current frame rate, compared to the solid-state imaging device before increasing the number of pixels. As described above, the technology to achieve high image quality at high frame rate is becoming essential.

In response to the request for the acceleration, the solid-state imaging device according to Patent Reference 1 (Japanese Unexamined Patent Application Publication No. 2005-347932) is provided with the two column signal lines 310 and 311 in one column of pixels in the pixel area (pixel array) 300 driven by the column scanning circuit 304 as shown in FIG. 5. The solid-state imaging device according to Patent Reference 1 achieves the acceleration by providing column circuits 301 and 305, AD converters (column ADCS) 302 and 306, and the row scanning circuits 303 and 307 respectively above and below the column signal lines 310 and 311, and by simultaneously selecting the pixel cells for two rows.

### SUMMARY OF THE INVENTION

However, in the solid-state imaging device according to Patent Reference 1 shown in FIG. 5 which simply includes column signal lines and column circuits each of which is for one of the column signal line, signals from the R pixels (the pixel cells on which R color filters are arranged) is output to the column signal line 310, and signals from the Gb pixels (the pixel cells on which Gb color filters are arranged) are output to the column signal line 311 provided in parallel with the column signal line 310, in consideration of the Bayer pattern of the color filters. This structure causes crosstalk due to coupling between the column signal lines 310 and 311 when there is a difference in the signal levels of the R pixels and the Gb pixels. Furthermore, the same phenomenon occurs between the Gr pixels and the B pixels. As a result, the difference between the signal level of the R pixels and the signal level of the B pixels leads to a difference in the intensity of the crosstalks, which causes a difference in the signal level of the Gr pixels and the signal level of the Gb pixels. This causes a problem that a uniform object image to be a rough image.

The present invention has been conceived to solve the above problem, and it is an object of the present invention to provide a solid-state imaging device capable of operating at high-speed, and suppressing the deterioration in image quality caused by coupling.

In order to achieve the above object, the solid-state imaging device according to the present invention includes: pixels arranged in rows and columns, each of which outputs a signal according to intensity of incident light; color filters each of which is arranged on a light incidence plane of a corresponding one of the pixels, each of the color filters being one of at least two colors; and two column signal lines provided for each of the columns of the pixels, and each of which transmits the signals from the pixels in a column direction, in which one of the color filters is arranged on one of the pixels connected to one of the two column signal lines, and is of a same color as another one of the color filters arranged on another one of the pixels connected to the other one of the two column signal line. Here, the solid-state imaging device may further include a column scanning circuit which controls the readout transistor to switch on and off, in which the column scanning circuit controls the readout transistors so that the readout transistors of the pixels in different rows on which the color filters of the same color are arranged are simultaneously switched on or off.

With this structure, the two column signal lines are connected to one column of the pixels. Thus, it is possible to simultaneously output the signals from the pixels in the same column and in different rows to separate column signal lines, allowing a high speed operation of the solid-state imaging device. Furthermore, this structure allows outputting signals from the pixels on which the color filters of the same color are arranged to the two column signal lines arranged in parallel included in the column signal lines. This structure allows eliminating the difference in signal levels of the pixels on which color filters of the same color are arranged, caused by the crosstalk between the column signal lines, and thus, it is possible to suppress the degradation in image quality caused by coupling.

Furthermore, each of the two column signal lines may be connected to a corresponding one of the pixels in different columns, and on which the color filters of the same color may be arranged. Furthermore, each of the pixels may further include: a photoelectric conversion unit which converts the incident light into signal charge by photoelectric conversion; and a readout transistor which reads the signal charge out of the photoelectric conversion unit, the solid-state imaging device may further includes a signal output unit including: a floating diffusion unit which holds the signal charge that has been read out of the photoelectric conversion unit; a reset transistor which resets an electric potential of the floating diffusion unit; and an amplifying transistor which outputs a voltage signal according to the electric potential of the floating diffusion unit, and the signal output unit may be inserted between the column signal lines and adjacent two of the pixels in different columns, and on which the color filters of the same color are arranged.

Further, each of the two column signal lines may be connected to a corresponding one of the pixels in a same column, and on which the color filters of different colors are arranged. Still further, each of the pixels may further include: a photoelectric conversion unit which converts the incident light into signal charge by photoelectric conversion; and a readout transistor which reads the signal charge out of the photoelectric conversion unit, the solid-state imaging device may further include a signal output unit including: a floating diffusion unit which holds the signal charge that has been read out of the photoelectric conversion unit; a reset transistor which resets an electric potential of the floating diffusion unit; and an amplifying transistor which outputs a voltage signal according to the electric potential of the floating diffusion unit, and the signal output unit may be inserted between the column signal lines and adjacent two of the pixels in the same column and on which the color filters of the different colors are arranged.

With this structure, the two pixels share the signal output unit. Thus, even in the structure including multiple column signal lines, the areas of the photoelectric conversion units will not be excessively small. Accordingly, it is possible to suppress reduction in sensitivity. Further, since the two adjacent pixels share the signal output unit, it is possible to suppress the difference in the signal level caused by a difference in layout.

Furthermore, the solid-state imaging device may further includes: a first column circuit and a second column circuit each of which is connected to a same column signal line, amplifies the signal from each of the pixels, and removes noise included in the signal from each of the pixels; a first switch inserted between one of the two column signal lines and the first column circuit; a second switch inserted between the one of the two column signal lines and the second column circuit; a third switch inserted between the other of the two column signal lines and the first column circuit; and a fourth switch inserted between the other of the two column signal lines and the second column circuit.

With this structure, the switches are arranged between the column signal lines which provide the signals from the pixels and the column circuits, and the signals from the pixels output to the column signal lines are sorted by the switches and input to each of the column circuits. This allows selecting column circuit to which the signals from the pixels in the selected row are input, and thus, it is possible to input the signals that the pixel mixture is to be performed to the same column circuit.

Furthermore, the structure between the switches and the column circuits may be a structure where output terminals of the switches are connected each other, and the column signal lines are connected to the column circuit as one signal line. Accordingly, only the column circuits as many as the number of the column signal lines are necessary, which allows reduction in the size of a chip.

Furthermore, the color filters may be arranged in the Bayer pattern, the two column signal lines may be respectively connected to the pixels on which green color filters are arranged.

This structure allows removing the difference in signal levels of the Gr pixels and the Gb pixels on which the green color filters are arranged, which make up half of the pixels in the Bayer pattern, caused by the crosstalk due to the difference in the signal levels of the Gr pixels and the Gb pixels and the signal levels of the R pixels and the B pixels. Therefore, it is possible to achieve high image quality.

The solid-state imaging device according to the present invention can implement a solid-state imaging device capable of operating at high-speed, and suppressing the influence of deterioration of image quality caused by coupling. Therefore, it is possible to provide a solid-state imaging device capable imaging a high quality image at high speed.

### FURTHER INFORMATION ABOUT TECHNICAL BACKGROUND TO THIS APPLICATION

The disclosure of Japanese Patent Application No. 2008-165859 filed on Jun. 25, 2008 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 illustrates the structure of the solid-state imaging device according to Embodiment 1 of the present invention;

FIG. 2 illustrates the structure of pixel cells according to Embodiment 1 of the present invention;

FIG. 3 illustrates the structure of the solid-state imaging device according to Embodiment 2 of the present invention;

FIG. 4 illustrates the structure of pixel cells according to Embodiment 2 of the present invention; and

FIG. 5 illustrates the structure of the solid-state imaging device according to Patent Reference 1.

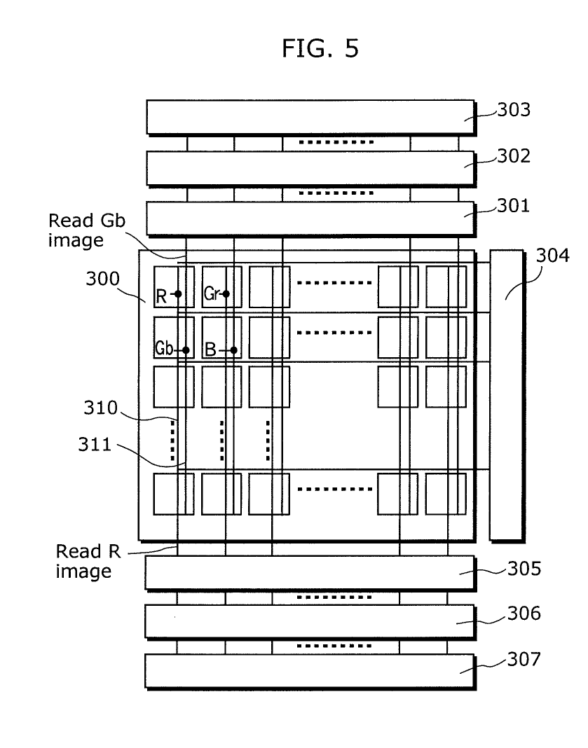

### DESCRIPTION OF THE PREFERRED EMBODIMENT(S)

The solid-state imaging device according to the present invention shall be described with reference to the drawings.

### Embodiment 1

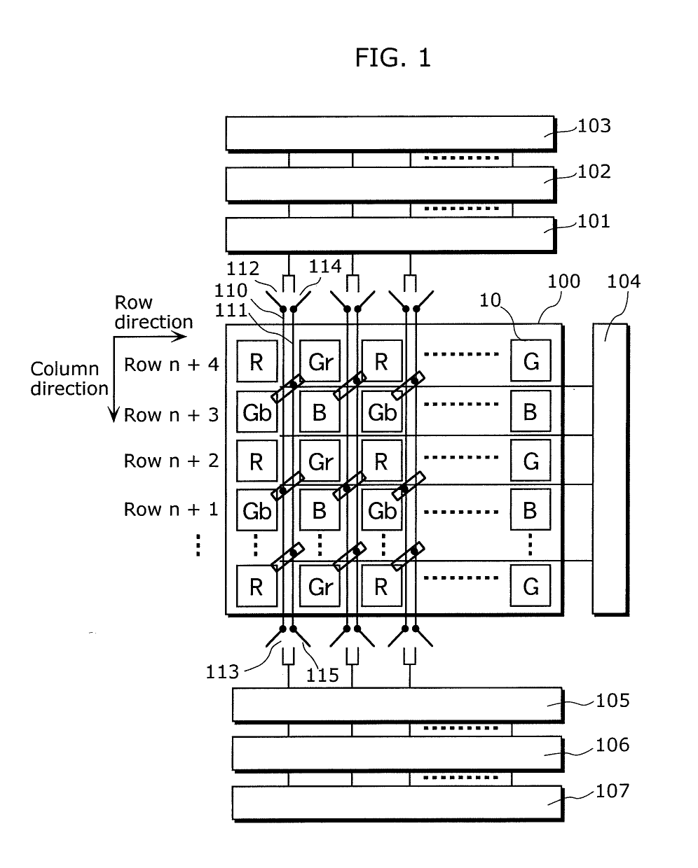

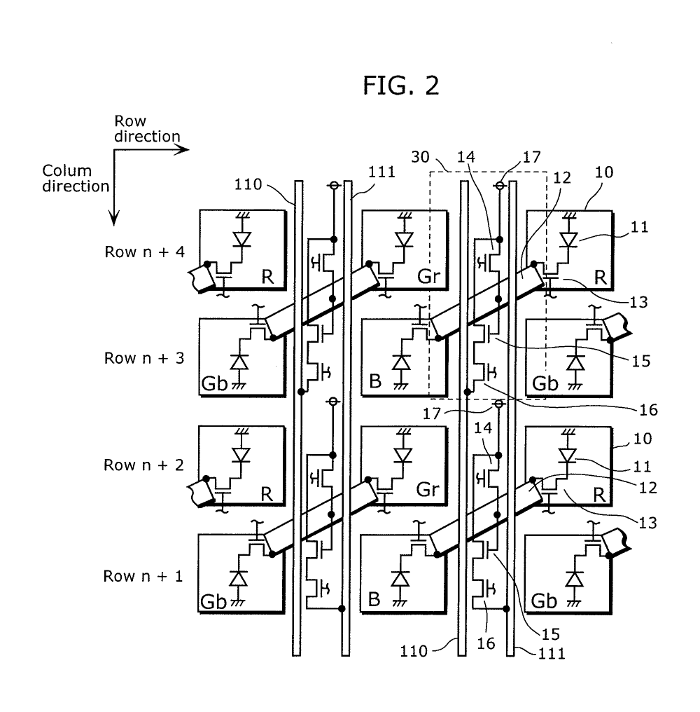

FIG. 1 illustrates the structure of the solid-state imaging device according to Embodiment 1 of the present invention, and FIG. 2 illustrates the structure of pixel cells 10 configuring a pixel area 100 of the solid-state imaging device.

The solid-state imaging device includes, as shown in FIG. 1, the pixel area 100 in which plural pixel cells 10 are arranged in a matrix form (in rows and columns), column circuits 101 and 105, AD converters 102 and 106, row scanning circuits 103 and 107, respectively provided above and below the pixel area 100 for each column of the pixel cell 10, a column scanning circuit 104, column signal lines 110 and 111 (the first column signal line 110 and the second column signal line 111), and switches 112, 113, 114, and 115.

Each of the pixel cells 10 outputs signals according to the intensity of incident light. Color filters having two or more colors are respectively arranged on the light incidence plane of the pixel cells 10. More specifically, the color filters of R, Gb, Gr and B are arranged in the Bayer pattern.

Among the pixel cells 10 configuring one column, the color filters of the same color as the color filters arranged on the pixel cells 10 connected to the column signal line 111 are arranged on the pixel cells 10 connected to the column signal line 110. Accordingly, the column signal lines 110 and 111 are respectively connected to the pixel cells 10 on which green color filters are arranged.

The column signal lines 110 and 111 are provided for each column of the pixel cells 10, and transmit the signals from the pixel cells 10 in the column direction. The column signal lines 110 and 111 are respectively connected to the pixel cells 10, and provided between adjacent columns of the pixel cells 10 next to each other. The column signal lines 110 and 111 are respectively connected to two pixel cells 10 on which the color filters of the same color (green) are arranged in different columns, more specifically, the Gb pixel and the Gr pixel. Alternatively, the column signal lines 110 and 111 are respectively connected to the two pixel cells 10 on which the color filters of the different colors are arranged in different columns, more specifically, the B pixel and the R pixel.

As shown in FIG. 2, the pixel area 100 includes the pixel cells 10, the column signal lines 110 and 111, and signal output units 30 for outputting the signals from the pixel cells 10.

Each of the pixel cells 10 includes a photoelectric conversion unit 11 such as a photodiode which performs photoelectric conversion on the incident light, and a readout transistor 13 which is inserted between the photoelectric conversion unit 11 and the floating diffusion unit 12, and reads signal charge from the photoelectric conversion unit 11 to the floating diffusion unit 12.

The signal output unit 30 includes the floating diffusion unit (charge detecting unit) 12 which holds the signal charge read out of the photoelectric conversion unit 11, a reset transistor 14 which resets the electric potential of the floating diffusion unit 12, an amplifying transistor 15 which outputs the signal voltage according to the electric potential of the floating diffusion unit 12, a selection transistor 16, and a pixel power supply 17.

The signal output unit 30 is inserted between the column signal line 110 or 111 and two adjacent pixel cells 10 in different columns on which the color filters of the same color (green) or different colors are arranged. The signal output unit 30 is shared between the diagonally adjacent pixel cells 10 on which color filters of the same color (green) are arranged (the two pixel cells 10 opposing each other with respect to the floating diffusion unit 12), or diagonally adjacent pixel cells 10 on which color filters of different colors are arranged. More specifically, the signal output unit 30 is shared between the diagonally adjacent Gb pixel and Gr pixel, or the diagonally adjacent B pixel and R pixel. Furthermore, the signal output unit 30 connected to the column signal line 110 and the signal output unit 30 connected to the column signal line 111 are arranged alternately in the column direction.

The column scanning circuit 104 includes a decoder circuit and a shift register and others which generate a drive signal input to the gates of: the readout transistor 13; the reset transistor 14; and a select transistor 16. The column scanning circuit 104 inputs the drive signal to each transistor and control ON and OFF of the readout transistor 13, the reset transistor 14, and the select transistor 16. The column scanning circuit 104 controls the readout transistors 13 so that the readout transistors of the pixel cells 10 in different rows on which color filters of the same color (green) are arranged are simultaneously switched ON or switched OFF.

Each of the select transistors 16 is provided between the amplifying transistor 15 and the column signal line 110 or 111, and reads the voltage signal to the column signal line 110 or 111. The structure in which the select transistor 16 is provided between the amplifying transistor 15 and the column signal line 110 and the structure in which the select transistor 16 is provided between the amplifying transistor 15 and the column signal line 111 are alternately formed in the column direction.

The column circuits 101 and 105 are connected to the same column signal lines 110 and 111, and each of which includes a circuit such as CDS (Correlated double sampling) for removing noise included in the analog signal from each pixel cell 10, and an amplifying circuit which amplifies the signal from each pixel cell 10.

The AD converters 102 and 106 respectively include circuits that compare a ramp waveform and the signal voltage from the pixel cell 10, count time period until the ramp waveform and the signal voltage from the pixel cells 10 match by counter circuits and others, and convert the analog signal into the digital signal.

The row scanning circuits 103 and 107 respectively include circuits such as shift registers.

The column signal lines 110 and 111 provided for each column of pixel cells 10, are respectively connected to the pixel cells 10 in the different rows in the pixel area 100, for example, the pixel cells 10 in the odd rows and the pixel cells 10 in the even rows, and are connected to the column circuits 101 and 105 via the switches 112, 113, 114, and 115. The switches 112, 113, 114, and 115 select one of the outputs from the pixel cells 10 to the column signal lines 110 and 111, so that the selected output is input to one of the column circuits 101 and 102.

The switch 112 is inserted between the column signal line 110 and the column circuit 101, and the switch 113 is inserted between the column signal line 110 and the column circuit 105. Similarly, the switch 114 is inserted between the column signal line 111 and the column circuit 101, and the switch 115 is inserted between the column signal line 111 and the column circuit 105. The switch 112 is made up of a transistor having a different polarity from the polarity of the transistor which is made up of the switch 114. Similarly, the switch 113 is made up of a transistor having a different polarity from the polarity of the transistor which makes up of the switch 115. For example, the switches 112 and 113 are respectively made up of n-type transistors, and the switches 114 and 115 are respectively made up of p-type transistors.

Next, the driving method (operation) of the solid-state imaging device according to Embodiment 1 of the present invention shall be described.

First, reset signals for resetting the floating diffusion units 12 provided for corresponding pixel cells 10 on plural rows are inputted to the reset transistors 14 from the column scanning circuit 104. Accordingly, the floating diffusion unit 12 shared by the pixel cells 10 in the row n+1 and the row n+2, and the floating diffusion unit 12 shared by the pixel cells 10 in the row n+3 and the row n+4 are reset, for example.

Subsequently, the read signals from the column scanning circuit 104 are input to the readout transistors 13, and the signals of the pixel cells 10 are read to the floating diffusion units 12 which have been reset. Afterwards, the column scanning circuit 104 inputs row selection signals to the select transistors 16, and the signals read by the floating diffusion units 12 are output to the column signal lines 110 and 111, and input to the column circuits 101 and 105. For example, the signals from the pixel cell 10 on the row n+1 (the Gb pixel in FIG. 1), is input to the column circuit 105 through the column signal line 111 and via the switch 115. The signals from the pixel cell 10 on the row n+4 (the Gr pixel in FIG. 1) is input to the column circuit 101 through the column signal line 110 and via the switch 112. Noise of the pixel cells 10 included in the respective input signals are removed by the CDS circuits and others in the column circuits 101 and 105.

Subsequently, the signals of which the noise is removed are respectively input to the AD converter 102 or 106 per column of the pixel cells 10, and the analog signals are converted to the digital signals.

Next, the digitally converted signals are respectively input to the row scanning circuit 103 or 107 per column of the pixel cells 10. Subsequently, the row scanning circuits 103 and 107 output signals for two rows of the pixel cells 10. All of the signals from the pixel cells 10 are output by performing this operation on all of the pixel cells 10 by the column scanning circuit 104 and sequentially driving the pixel cells 10 in different rows.

As described above, the solid-state imaging device according to Embodiment 1 has a structure including plural column signal lines corresponding to each column of the pixel cells 10. This allows pixel signals from different rows to be simultaneously output to different column signal lines, which achieves a high frame rate. Furthermore, the column scanning circuit 104 sets the rows of the pixel cells 10 to read signals simultaneously to the column signal lines provided next to each other as the rows having the same color, more specifically, the rows of the Gr pixels and the rows of the Gb pixels.

Therefore, even if plural column signal lines are provided for a column of the pixel cells 10, it is possible to remove the difference in signal levels of the Gr pixels and the Gb pixels caused by the crosstalk due to the coupling between the column signal lines, and to achieve high image quality.

Next, a pixel mixture operation in the driving method (operation) of the solid-state imaging device according to Embodiment 1 of the present invention shall be described. Here, although an operation for mixing the signals from the two pixel cells 10 shall be described for simplification of the description, the number of the pixel cells 10 to be mixed is not particularly limited.

First, the column scanning circuit 104 selects plural rows as the rows of the pixel cells 10 from which the signals are read to the column signal lines 110 and 111. With this, for example, the signal from the pixel cell 10 in the row n+1 is output to the column signal line 111, and input to the column circuit 105 through the column signal line 111 and via the switch 115. In the same manner, the signal from the pixel cell 10 in the row n+4 is output to the column signal line 110, and input to the column circuit 101 through the column signal line 110 and via the switch 112. Subsequently, the noise in the signal from the pixel cell 10 is removed by CDS circuit and others.

Subsequently, the signals of which the noise is removed are respectively input to the AD converter 102 or 106 per column of the pixel cells 10, and the digitally converted signals are temporally held.

Next, the column scanning circuit 104 selects plural rows as the rows of pixel cells 10 from which the signals are read to the column signal lines 110 and 111. With this, for example, the signal from the pixel cell 10 in the row n+2 is output to the column signal line 111, and input to the column circuit 101 through the column signal line 111 and via the switch 114, and input to the AD converter 102 per column of the pixel cell 10 passing through a CDS circuit and others. Similarly, the pixel cell 10 in the row n+3 passes through the column signal line 110 and input to the column circuit 105 via the switch 113, and input to the AD converter 106 per column of the pixel cells 10 passing through a CDS circuit and others.

Subsequently, the AD converter 102 converts the analog signal from the pixel cell in the row n+2 to a digital signal, and adds the digital signal to the digital signal of the pixel cell 10 in the row n+4 that has been held. Similarly, the AD converter 106 converts an analog signal from the pixel cell 10 in the row n+3 to a digital signal, and adds the digital signal to the digital signal of the pixel cell 10 in the row n+1 that has been held.

Then, the digitally converted signals are respectively input to the row scanning circuit 103 or 107 per each column. The signals from the pixel cells 10 in different columns are sequentially output from the row scanning circuits 103 and 107.

As described above, according to the solid-state imaging device according to Embodiment 1, with the switching of the switches 112, 113, 114 and 115 provided between the column circuits 101 and 105 and the column signal lines 110 and 111, it is possible to input the output from the pixel cells 10 to perform pixel mixture operation to a given column circuits 101 and 105. Accordingly, various combinations of pixel mixture operation drive are achieved. Furthermore, very high-speed pixel addition operation is achieved since pixel cells 10 in plural rows are simultaneously selected and output to the column signal lines 110 and 111.

### Embodiment 2

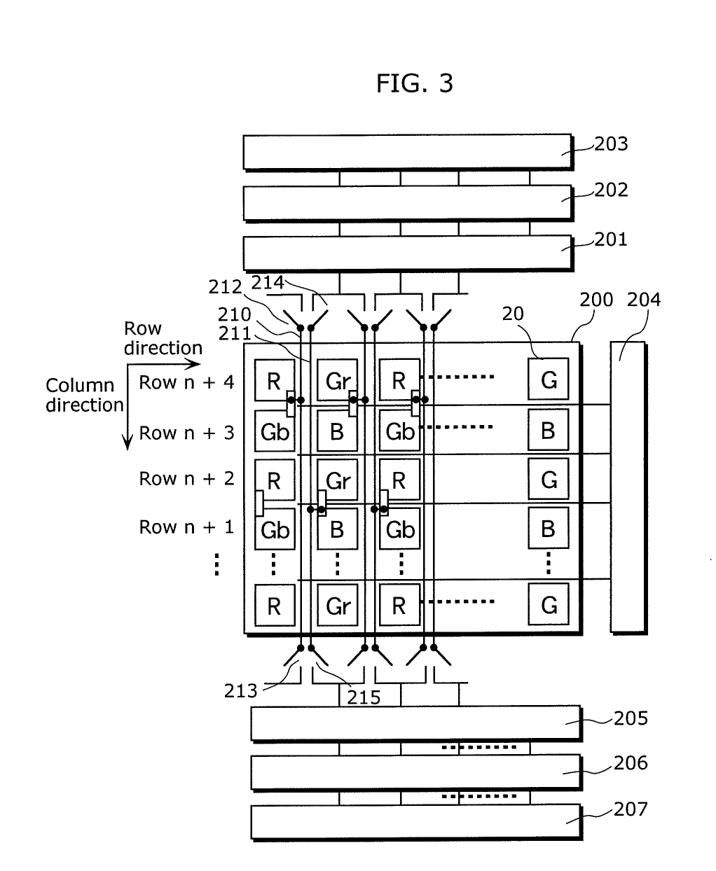

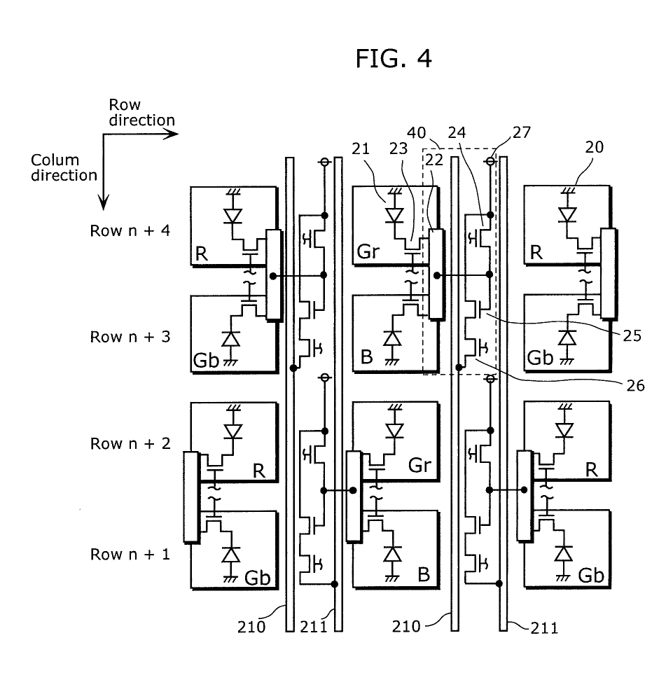

FIG. 3 illustrates the structure of the solid-state imaging device according to Embodiment 2 of the present invention. Furthermore, FIG. 4 illustrates the structure of pixel cells 20 in the solid-state imaging device. Note that the structure other than the structure illustrated in FIGS. 3 and 4 which shall be described later is identical to the solid-state imaging device according to Embodiment 1 of the present invention.

The solid-state imaging device includes, as shown in FIG. 3, the pixel area 200 in which plural pixel cells 20 are arranged in a matrix form, column circuits 201 and 205, AD converters 202 and 206, row scanning circuits 203 and 207, respectively provided above and below the pixel area 200 for each column of the pixel cells 20, a column scanning circuit 204, column signal lines 210 and 211 (the first column signal line 210 and the second column signal line 211), and switches 212, 213, 214, and 215.

Each of the pixel cells 20 outputs signals according to the intensity of incident light. Color filters having two or more colors are respectively arranged on the light incidence plane of the pixel cells 20. More specifically, the color filters of R, Gb, Gr and B are arranged in the Bayer pattern.

Among the pixel cells 20 configuring one column, the color filters of the same color as the color filters arranged on the pixel cells 20 connected to the column signal line 211 are arranged on the pixel cells 20 connected to the column signal line 210. Accordingly, the column signal lines 210 and 211 are respectively connected to the pixel cells 20 on which green color filters are arranged.

The column signal lines 210 and 211 are provided for each column of the pixel cells 20, and transmit the signals from the pixel cells 20 in the column direction. The column signal lines 210 and 211 are respectively connected to the pixel cells 20, and provided between adjacent columns of the pixel cells 20 next to each other. The column signal lines 110 and 111 are respectively connected to two pixel cells 20 on the same column on which color filters of different colors are arranged, namely, R pixels and Gb pixels, or Gr pixels and B pixels.

As shown in FIG. 4, the pixel area 200 includes the pixel cells 20, the column signal lines 210 and 211, and a signal output unit 40 for outputting the signals from the pixel cells 20.

Each of the pixel cells 20 includes a photoelectric conversion unit 21 such as a photodiode, which performs photoelectric conversion on the incident light, and a readout transistor 23 which is inserted between the photoelectric conversion unit 21 and the floating diffusion unit 22, and reads signal charge from the photoelectric conversion unit 21 to the floating diffusion unit 22.

The signal output unit 40 includes the floating diffusion unit (charge detecting unit) 22 which holds the signal charge read out of the photoelectric conversion unit 21, a reset transistor 24 which resets the electric potential of the floating diffusion unit 22, an amplifying transistor 25 which outputs the signal voltage according to the electric potential of the floating diffusion unit 22, a selection transistor 26, and a pixel power supply 27.

The signal output unit 40 is inserted between the column signal line 210 or 211 and two adjacent pixel cells 20 in the same column on which the color filters of the different colors are arranged. The signal output unit 40 is shared by the adjacent pixel cells 20 in the column direction on which color filters of different colors are arranged. More specifically, the signal output unit 40 is shared by the R pixels and the Gb pixels, or the Gr pixels and the B pixels that are adjacent in the column direction. Furthermore, the signal output unit 40 connected to the column signal line 210 and the signal output unit 40 connected to the column signal line 211 are arranged alternately in the column direction.

The column scanning circuit 204 includes a decoder circuit and a shift register and others which generate a drive signal input to the gates of: the readout transistor 23; the reset transistor 24; and a select transistor 26. The column scanning circuit 204 inputs the drive signal to each transistor and control ON and OFF of the readout transistor 23, the reset transistor 24, and the select transistor 26. The column scanning circuit 204 controls the readout transistors 23 so that the readout transistors of the pixel cells 20 in different rows on which color filters of the same color (green) are arranged are simultaneously switched ON or switched OFF.

Each of the select transistors 26 is provided between the amplifying transistor 25 and the column signal line 210 or 211, and reads the voltage signal to the column signal line 210 or 211. The structure in which the select transistor 26 is provided between the amplifying transistor 25 and the column signal line 210 and the structure in which the select transistor 26 is provided between the amplifying transistor 25 and the column signal line 211 are alternately formed in the column direction.

The column circuits 201 and 205 are connected to the same column signal lines 210 and 211, and each of which includes a circuit such as CDS (Correlated double sampling) for removing noise included in the analog signal from each pixel cell 20, and an amplifying circuit which amplifies the signal from each pixel cell 20.

The AD converters 202 and 206 respectively include circuits that compare a ramp waveform and the signal voltage from the pixel cell 20, count time period until the ramp waveform and the signal voltage from the pixel cells 20 match by counter circuits and others, and convert the analog signal into the digital signal.

The row scanning circuits 203 and 207 respectively include circuits such as shift registers.

The column signal lines 210 and 211 provided for each column of pixel cells 20 are respectively connected to the column circuits 201 and 205 via the switches 212, 213, 214, and 215. The switches 212, 213, 214, and 215 select one of the outputs from the pixel cells 20 to the column signal lines 210 and 211, so that the selected output is input to one of the column circuits 201 and 202.

The switch 212 is inserted between the column signal line 210 and the column circuit 201, and the switch 213 is inserted between the column signal line 210 and the column circuit 205. Similarly, the switch 214 is inserted between the column signal line 211 and the column circuit 201, and the switch 215 is inserted between the column signal line 211 and the column circuit 205. The switch 212 is made up of a transistor having a different polarity from the polarity of the transistor which is made up of the switch 214. Similarly, the switch 213 is made up of a transistor having a different polarity from the polarity of the transistor which makes up of the switch 215. For example, the switches 212 and 213 are respectively made up of n-type transistors, and the switches 214 and 215 are respectively made up of p-type transistors.

Next, the driving method (operation) of the solid-state imaging device according to Embodiment 2 of the present invention shall be described.

First, reset signals for resetting the floating diffusion units 22 provided for corresponding pixel cells 20 on plural rows are inputted to the reset transistors 24 from the column scanning circuit 204. Accordingly, the floating diffusion unit 22 shared by the pixel cells 20 in the row n+1 and the row n+2, and the floating diffusion unit 22 shared by the pixel cells 20 in the row n+3 and the row n+4 are reset, for example.

Subsequently, the read signals from the column scanning circuit 204 are input to the readout transistors 23, and the signals of the pixel cells 20 are read to the floating diffusion units 22 which have been reset. Afterwards, the column scanning circuit 204 inputs row selection signals to the select transistors 26, and the signals read to the floating diffusion units 22 are output to the column signal lines 210 and 211, and input to the column circuits 201 and 205. For example, the signals from the pixel cell 20 on the row n+2 (a Gr pixel signal, for example), is input to the column circuit 205 through the column signal line 211 and via the switch 215. The signals from the pixel cell 20 on the row n+3 (a Gb pixel signal, for example) is input to the column circuit 201 through the column signal line 210 and via the switch 212. Noise of the pixel cells 20 included in the respective input signals are removed by the CDS circuits and others in the column circuits 201 and 205.

Subsequently, the signals of which the noise is removed are respectively input to the AD converter 206 or 202 per column of the pixel cells 20, and the analog signals are converted to the digital signals.

Next, the digitally converted signals are respectively input to the row scanning circuit 203 or 207 per column of the pixel cells 20. Subsequently, the row scanning circuits 203 and 207 output signals for two rows of the pixel cells 20. All of the signals from the pixel cells 20 are output by performing this operation on all of the pixel cells 20 by the column scanning circuit 204 and sequentially driving the pixel cells 20 in different rows.

As described above, the solid-state imaging device according to Embodiment 2, the column scanning circuit 204 sets the rows of the pixel cells 20 to be simultaneously read as rows having same color, more specifically, the rows of the Gr pixels and the rows of the Gb pixels. Accordingly, it is possible to suppress the difference in signal levels of the Gr pixels and the Gb pixels caused by the crosstalk due to the coupling between the column signal lines, and to achieve high image quality at a high frame rate

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

For example, the description has been made that the circuit which reads the signals from the pixel cells includes four transistors, namely, the readout transistor, the reset transistor, the amplifying transistor, and the select transistor. However, the same effect can be achieved with a three-transistor structure which does not includes the select transistor and is driven using the pixel power supply as pulse. Thus, the structure of the circuit is not limited to the Embodiments described above.

### INDUSTRIAL APPLICABILITY

The present invention is effective for solid-state imaging devices, and particularly for an MOS solid-state imaging device on which color filters in the Bayer pattern are incorporated.

What is claimed is:

1. A solid-state imaging device comprising:
pixels arranged in rows and columns, each of which outputs a signal according to intensity of incident light;
color filters each of which is arranged on a light incidence plane of a corresponding one of said pixels, each of said color filters being one of at least two colors; and
two column signal lines provided for each of the columns of said pixels, and each of which transmits the signals from said pixels in a column direction,
wherein one of said color filters is arranged on one of said pixels connected to one of said two column signal lines, and is of a same color as another one of said color filters arranged on another one of said pixels connected to the other one of said two column signal line.

2. The solid-state imaging device according to claim 1,
wherein each of said two column signal lines is connected to a corresponding one of said pixels in different columns, and on which said color filters of the same color are arranged.

3. The solid-state imaging device according to claim 2,
wherein each of said pixels further includes:
a photoelectric conversion unit configured to convert the incident light into signal charge by photoelectric conversion; and
a readout transistor which reads the signal charge out of said photoelectric conversion unit,
said solid-state imaging device further comprises
a signal output unit including:
a floating diffusion unit configured to hold the signal charge that has been read out of said photoelectric conversion unit;
a reset transistor which resets an electric potential of said floating diffusion unit; and
an amplifying transistor which outputs a voltage signal according to the electric potential of said floating diffusion unit, and
said signal output unit is inserted between said column signal lines and adjacent two of said pixels in different columns, and on which said color filters of the same color are arranged.

4. The solid-state imaging device according to claim 3, further comprising
a column scanning circuit which controls said readout transistor to switch on and off,
wherein said column scanning circuit controls said readout transistors so that said readout transistors of said pixels in different rows on which said color filters of the same color are arranged are simultaneously switched on or off.

5. The solid-state imaging device according claim 1,
wherein each of said two column signal lines is connected to a corresponding one of said pixels in a same column, and on which said color filters of different colors are arranged.

6. The solid-state imaging device according to claim 5,
wherein each of said pixels further includes:
a photoelectric conversion unit configured to convert the incident light into signal charge by photoelectric conversion; and
a readout transistor which reads the signal charge out of said photoelectric conversion unit,
said solid-state imaging device further comprises
a signal output unit including:
a floating diffusion unit configured to hold the signal charge that has been read out of said photoelectric conversion unit;
a reset transistor which resets an electric potential of said floating diffusion unit; and
an amplifying transistor which outputs a voltage signal according to the electric potential of said floating diffusion unit, and
said signal output unit is inserted between said column signal lines and adjacent two of said pixels in the same column and on which said color filters of the different colors are arranged.

7. The solid-state imaging device according to claim 6, further comprising
a column scanning circuit which controls said readout transistor to switch on and off,
wherein said column scanning circuit controls said readout transistors so that said readout transistors of said pixels in different rows on which said color filters of the same color are arranged are simultaneously switched on or off.

8. The solid-state imaging device according to claim 7,
said solid-state imaging device further comprising:
a first column circuit and a second column circuit each of which is connected to a same column signal line, amplifies the signal from each of said pixels, and removes noise included in the signal from each of said pixels;
a first switch inserted between one of said two column signal lines and said first column circuit;
a second switch inserted between the one of said two column signal lines and said second column circuit;
a third switch inserted between the other of said two column signal lines and said first column circuit; and
a fourth switch inserted between the other of said two column signal lines and said second column circuit.

9. The solid-state imaging device according to claim 8,
wherein said color filters are arranged in the Bayer pattern, and
said two column signal lines are respectively connected to said pixels on which green color filters are arranged.

10. The solid-state imaging device according to claim 1,
said solid-state imaging device further comprising:
a first column circuit and a second column circuit each of which is connected to a same column signal line, amplifies the signal from each of said pixels, and removes noise included in the signal from each of said pixels;
a first switch inserted between one of said two column signal lines and said first column circuit;
a second switch inserted between the one of said two column signal lines and said second column circuit;
a third switch inserted between the other of said two column signal lines and said first column circuit; and
a fourth switch inserted between the other of said two column signal lines and said second column circuit.

11. The solid-state imaging device according to claim 1,
wherein said color filters are arranged in the Bayer pattern,
said two column signal lines are respectively connected to said pixels on which green color filters are arranged.
